(19) United States
(12) Patent Application Publication
(10) Pub. No.: US 2017/0101720 A1
(43) Pub. Date: Apr. 13, 2017

(54) HARDENED TITANIUM ALLOY AND METHOD OF MAKING THE SAME

(71) Applicant: CSA Group LLC., Port St. Lucie, FL (US)

(72) Inventors: William D. HURST, Fort Pierce, FL (US); Glenn E. CAUTHREN, Palm City, FL (US)

(73) Assignee: CSA GROUP LLC., Port St. Lucie, FL (US)

(21) Appl. No.: 14/878,031

(22) Filed: Oct. 8, 2015

(51) Int. Cl. C25D 3/66; C23C 16/06; C22C 14/00; C25D 11/00

(52) U.S. Cl. CPC C25D 3/66; C25D 11/00; C23C 16/06; C22C 14/00

(57) ABSTRACT

According to an exemplary embodiment, a gas turbine element made of a hardened titanium alloy may be provided. The hardened titanium alloy may be made by a process which may include but may not be limited to, obtaining an element made of titanium alloy, treating a surface of the element made of titanium alloy with beryllium using diffusion process, and forming a titanium beryllide diffusion layer to a predetermined depth from the surface.

### BACKGROUND OF THE INVENTION

Titanium alloys are made of a combination of titanium and other elements. Many titanium alloys possess exceptional tensile strength and durability. Titanium alloys typically combine light weight, corrosion resistance, and an ability to retain their properties at extremely high or low temperatures. However, titanium alloys can be expensive to produce and are therefore generally reserved for applications such as aeronautics, medical devices, premium sports equipment, and electronics. Titanium is typically alloyed with pre-determined amounts of various elements, according to the desired application. For example, the elements introduced may be intended to give superior structural strength, biocompatibility properties, or other desired characteristics to the pure titanium.

However, changing the properties of titanium by the addition of other elements, may negatively affect the surface durability of the material. For example, surgical implants developed for hip joint replacements are made of an alloy with high strength and excellent biocompatibility, but show poor surface wear properties. Being able to locally change the properties of titanium alloy, to increase the durability of its surface, would have tremendous benefits for leading industries such as aerospace or medical devices.

### SUMMARY OF THE INVENTION

According to an exemplary embodiment, a turbine element, including, but not limited to, rotor blades, nozzle guide vanes, compressor vanes, turbine vanes, and turbine nozzle rings of gas turbine engines may be treated with beryllium to improve its resistance, hardness and/or durability. The beryllium treatment may utilize a fused salt electrolysis process and may allow the beryllium to be diffused into a layer at the surface of the turbine element. A variety of titanium alloys may be treated with beryllium. This treatment may produce elements with increased resistance and thereby extend the life of the elements.

According to a second exemplary embodiment, a hardened titanium alloy may be provided. The hardened titanium alloy may be made by a process which may include but is not limited to, obtaining an element made of titanium alloy, treating a surface of the element made of titanium alloy with beryllium using a diffusion process and forming a titanium beryllide layer to a predetermined depth from the surface.

According to another exemplary embodiment, a method of making hardened titanium alloy may be provided. The method of making hardened titanium alloy may include but may not be limited to: obtaining an element made of titanium alloy, treating a surface of the titanium alloy with beryllium using a diffusion process, and forming a titanium beryllide diffusion layer to a predetermined depth from the surface.

### BRIEF DESCRIPTION OF THE DRAWINGS

Advantages of embodiments of the present invention will be apparent from the following detailed description of the exemplary embodiments. The following detailed description should be considered in conjunction with the accompanying figures in which:

FIG. 1 may show a titanium rotor blade having a surface treated with beryllium so as to improve the surface hardness of the element.

FIG. 2 may show a titanium nozzle guide vane having a surface treated with beryllium so as to improve the surface hardness of the element.

FIG. 3 may show a titanium compressor vane having a surface treated with beryllium so as to improve the surface hardness of the element.

FIG. 4 may show a titanium turbine vane having a surface treated with beryllium so as to improve the surface hardness of the element.

FIG. 5 may show part of a titanium turbine nozzle ring having a surface treated with beryllium so as to improve the surface hardness of the element.

FIG. 6 may show an illustration of a cross section of a titanium alloy element.

FIG. 7 may show an illustration of the electrolytic molten salt deposition.

FIG. 8 may show an illustration of a method of making a hardened titanium alloy element.

FIG. 9 may show an illustration of a method of electrolytic molten salt deposition.

### DETAILED DESCRIPTION

Aspects of the present invention are disclosed in the following description and related figures directed to specific embodiments of the invention. Those skilled in the art will recognize that alternate embodiments may be devised without departing from the spirit or the scope of the claims. Additionally, well-known elements of exemplary embodiments of the invention will not be described in detail or will be omitted so as not to obscure the relevant details of the invention.

As used herein, the word “exemplary” means “serving as an example, instance or illustration.” The embodiments described herein are not limiting, but rather are exemplary only. It should be understood that the described embodiments are not necessarily to be construed as preferred or advantageous over other embodiments. Moreover, the terms “embodiments of the invention”, “embodiments” or “invention” do not require that all embodiments of the invention include the discussed feature, advantage or mode of operation.

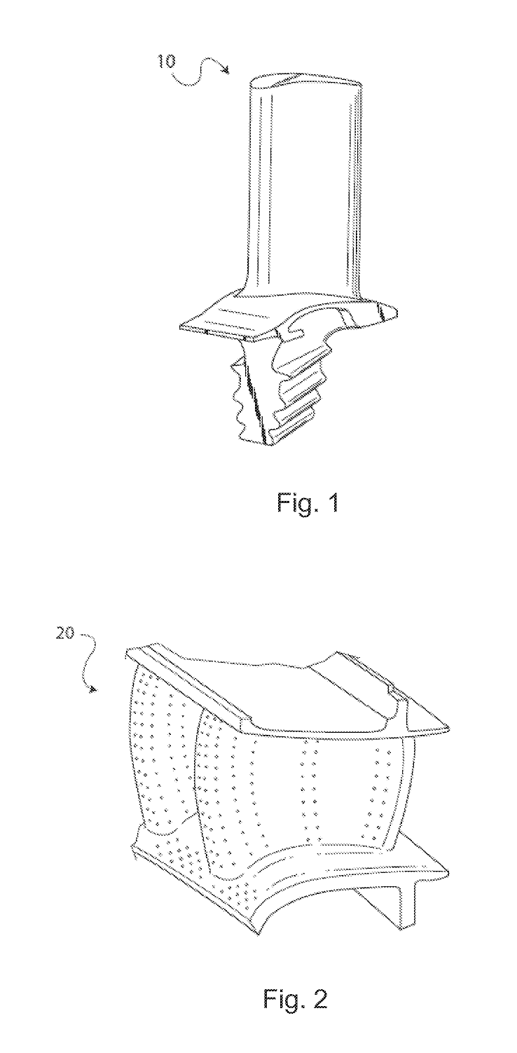

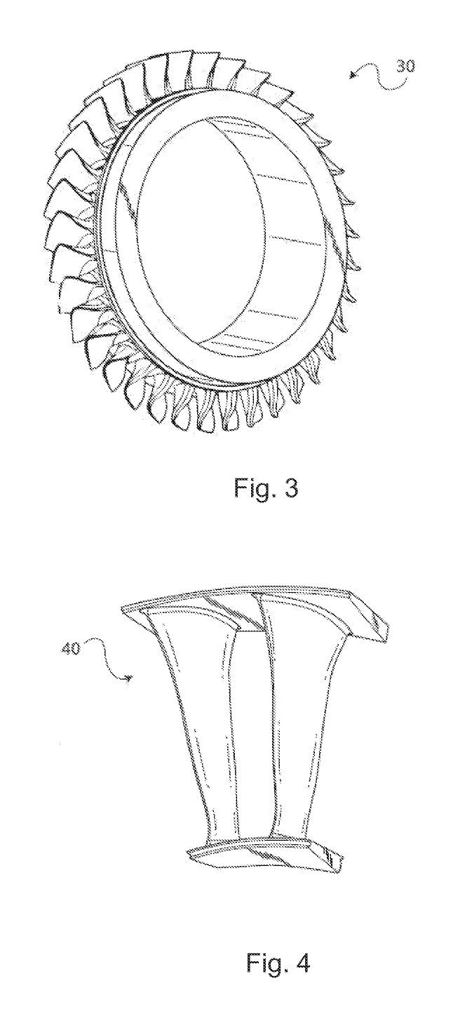

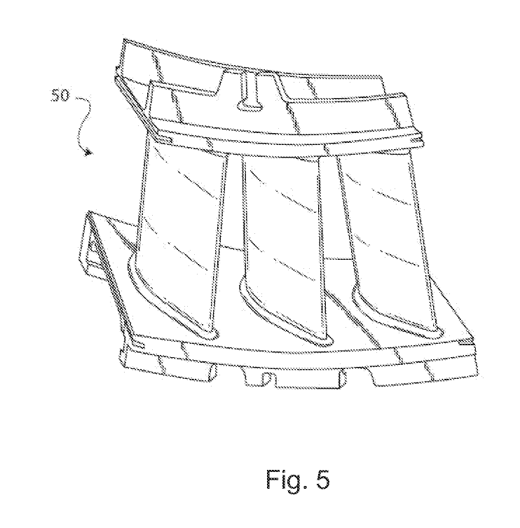

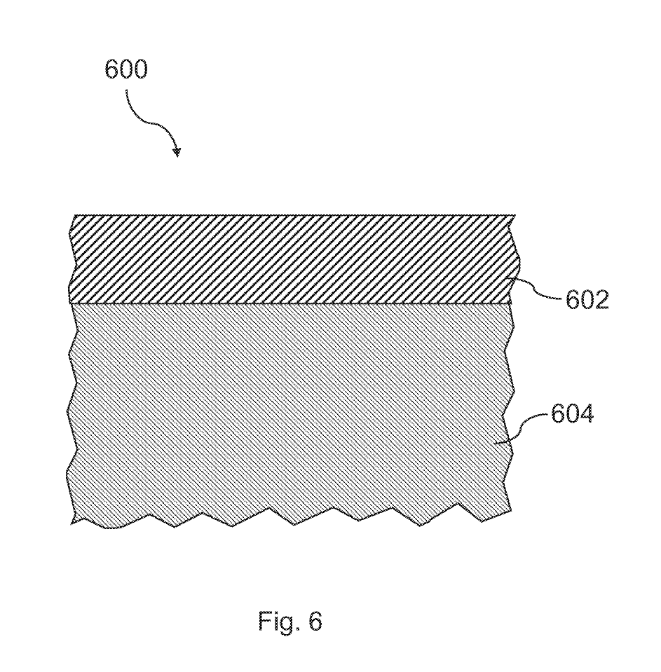

FIGS. 1-5 may generally illustrate examples of turbine elements for a gas turbine engine. Turbine elements may include, but not be limited to, a rotor blade 10 (shown in FIG. 1), a nozzle guide vane 20 (shown in FIG. 2), a turbine nozzle ring 30 (shown in FIG. 3), a compressor vane 40 (shown in FIG. 4), and a turbine vane 50 (shown in FIG. 5). The turbine elements may be constructed out of titanium alloy and may be treated by a beryllium diffusion processes to achieve improved hardness and durability. The turbine elements may be the type found in gas turbine engines used in aviation and industrial applications, but may not be limited to such uses.

In an exemplary embodiment illustrated in FIG. 6, a hardened titanium alloy element 600 may be made of a titanium alloy 604 and a titanium beryllide layer 602. The titanium alloy 604 may include, but not be limited to, Beta C² titanium, Ti6Al4V, Ti-6Al-4V, Ti 6-4 (may contain about 90% titanium, about 6% aluminum, and about 4% vanadium), and Ti-6Al-7Nb. It may be appreciated that the titanium alloy 604 may be of any desired chemical and structural composition, as may be understood by a person having ordinary skill in the art. It may be further appreciated that the titanium alloy element 600 may be of any desired form and function including a surgical implant, a medical device, an industrial tool, a mechanical part, a piece of drilling equipment, a gas turbine element, an aircraft landing gear element, or any other desired element as would be understood by a person having ordinary skill in the art.

Still referring to exemplary FIG. 6, beryllium compounds may undergo a process to be diffused into the titanium alloy 604 and create a titanium beryllide layer 602. In an exemplary embodiment, the titanium beryllide layer 602 onto titanium alloy element 600 may have a depth from approximately 0.0005 inch to approximately 0.001 inch, including a 0.0001 inch dimensional increase of the overall element. It may be appreciated that the depth of the titanium beryllide layer 602 may be of any desired value and may depend on the titanium alloy 604. The primary titanium beryllide formed may be TiBe which may be metastable. It may be appreciated that other titanium beryllides, such as TiBe2, TiBe12, α and β Ti2Be17, may also be present. In an exemplary embodiment, the titanium beryllide layer 602 may be uniform over the entire surface of the titanium alloy element 600. Further, the titanium beryllide layer 602 may be corrosion resistant and its hardness may be approximately 900 HV (on the Vickers hardness scale).

In an exemplary embodiment, titanium beryllide layer 602 may optionally be formed by a number of methods such as, but not limited to, chemical vapor deposition, pack cementation, ion beam deposition, or fused salt electrolysis. It may be appreciated that any desired method resulting in a titanium beryllide layer 602 may be utilized, as would be understood by a person having ordinary skills in the art.

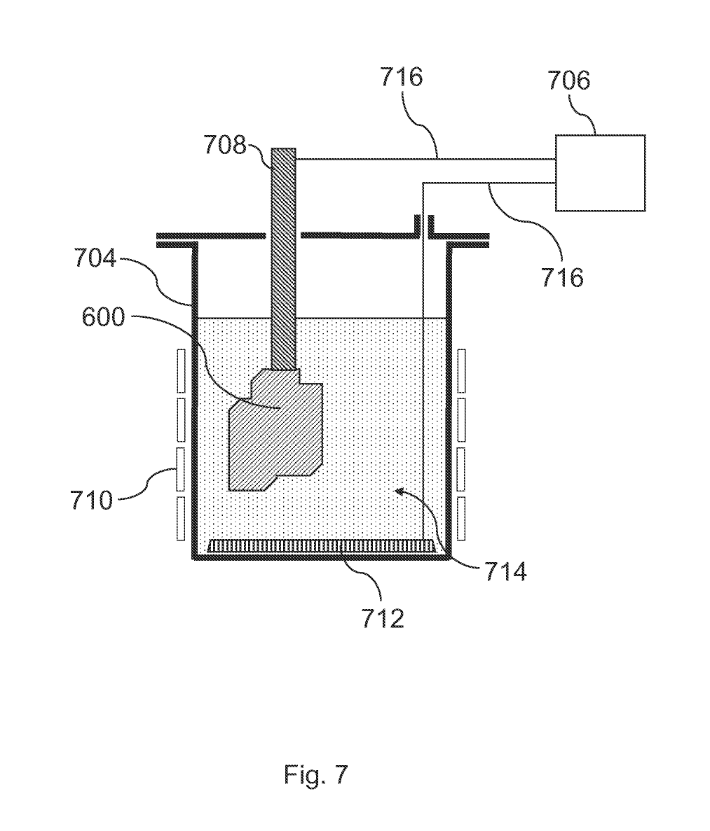

In at least one exemplary embodiment illustrated in FIG. 7, a fused salt electrolysis process may be used to diffuse beryllium into a titanium alloy element 600. The fused salt electrolysis may take place in a pressurized reactor 704 surrounded by heating elements. The titanium alloy element 600 may be attached to an electrode 708 and plunged into fused electrolyte 714. The electrode 708 may be connected to the power supply 706 with electrical wires 716. A second electrode 712 may be connected to the power supply 706 with electrical wires 716 and may be sunk in the fused salt electrolyte to complete the electrical circuit. The beryllium compound may be introduced as part of the electrode material or may be introduced directly in the fused salt electrolyte.

In a further exemplary embodiment, cathode baskets may be made of stainless steel screens and may be filled with titanium turnings. The titanium turnings may be used to control the diffusion of titanium beryllide on the titanium alloy element 600 until a satisfactory coating may be formed on the titanium element, as would be understood by a person having ordinary skill in the art.

The fused salt electrolyte may be maintained at a temperature from approximately 550° C. to approximately 1100° C. It may be appreciated that the fused salt electrolyte may be maintained at any desired temperature, up to the melting point of the substrate metal. It may be appreciated that the temperature may affect the speed of the process and may result in a faster transfer from anode to cathode. In an exemplary embodiment, the fused salt bath may include, but not be limited to, alkali metal fluorides, strontium fluorides, beryllium fluorides, and barium fluorides. Further, the fused salt electrolyte may contain any desired salt or mixture of salts. Generally, the process may be operated in the substantial absence of oxygen, carbon, organic and inorganic compounds. The reactor may be sealed and argon or any desired inert gas may be used to maintain a substantially oxygen-free atmosphere in the reaction vessel as may be understood by a person having ordinary skill in the art.

In an exemplary embodiment, beryllium compounds may be employed as an electrode and may be immersed in a fused salt electrolyte. The fused salt electrolyte may include approximately 0.3 mole percent to approximately 66 mole percent of beryllium fluoride, and optionally one or more additional alkali metal fluorides. The beryllium compounds may dissolve in the fused salt bath and beryllium ions may be diffused at the surface of the titanium cathode where they may form a diffused titanium beryllide layer.

In another exemplary embodiment, the current flowing in the electric cell may be controlled such that the current density of the cathode does not exceed 3 amperes per square decimeter (or 193 mA/in²) during the formation of the titanium beryllide layer 602. Further, the flow of electrical current may be interrupted once the beryllide layer 602 on the titanium alloy element 600 has reached a desired depth. In an exemplary embodiment, it may also be appreciated that during the diffusion of beryllium, the theoretical gain may be of approximately 0.168 g of beryllium for 1 ampere-hour of electrolysis.

In a further exemplary embodiment, the beryllium diffusion by the fused salt electrolysis process may be carried out in a reaction vessel made of a nickel-chromium-based alloy. An example of nickel-chromium-based alloy may be INCONEL®. It may be appreciated that traces of beryllium may get into the fused salt electrolyte from oxidation of the reaction vessel by air. Alternatively, the diffusion may be carried out in a reaction vessel made of nickel-copper-based alloy. An example of nickel-copper-based alloy may be MONEL®. It may be appreciated that any desired material may be used for the reaction vessel, as would be understood by a person having ordinary skills in the art.

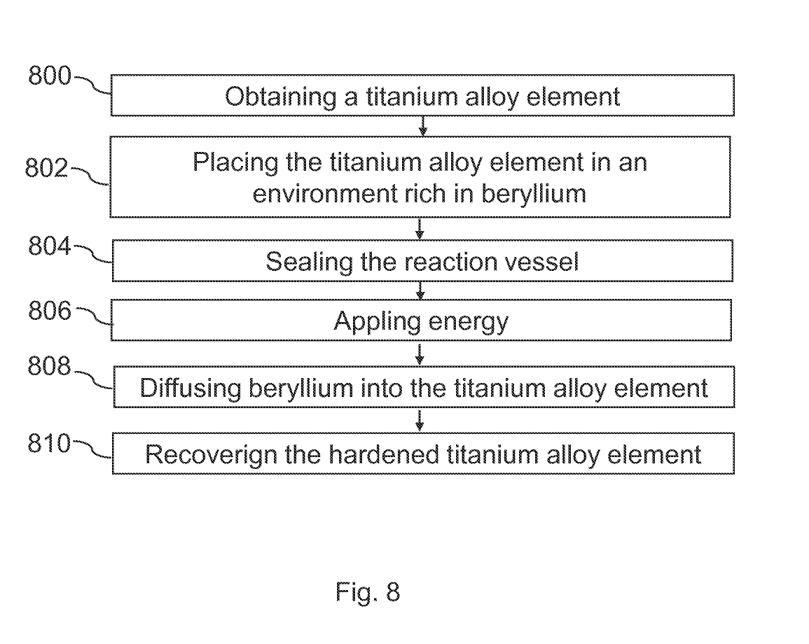

A general method of making a hardened titanium alloy element 600 may be provided and illustrated in FIG. 8. A titanium alloy element may be obtained 800, then placed in an environment rich in beryllium 802. The reaction vessel (or reactor) may be sealed 804 and energy may be applied 806. The beryllium may be diffused 808 into the titanium alloy element. Finally, the titanium alloy element may be recovered 810. Beryllium compounds and precursors may be in solid, liquid or gaseous phases and it may be appreciated that the energy may be applied in any desired form, such as, but not limited to, heat, laser, pressure, electrical current, or plasma.

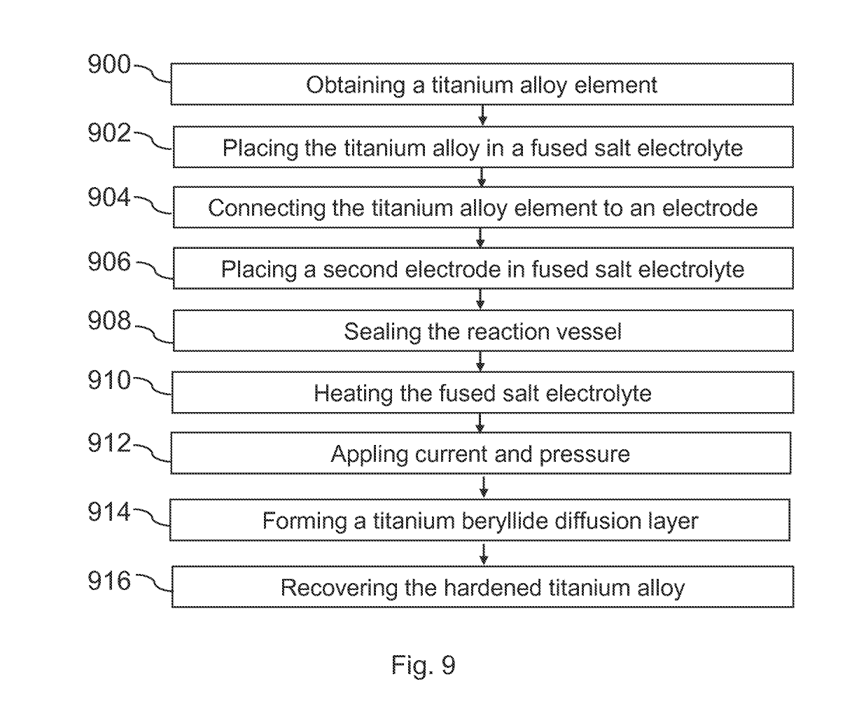

A method of making a hardened titanium alloy element may be provided and illustrated in FIG. 9. A titanium alloy element may be obtained 900, then placed in a fused salt electrolyte 902. The titanium alloy element may be connected to an electrode 904 and a second electrode may be placed in the same fused salt electrolyte 906. The reaction vessel (or reactor) may be sealed 908 and the fused salt electrolyte may be heated 910. Next, electrical current and pressure may be applied 912 and the beryllium may be diffused into the titanium alloy element 600, forming a titanium beryllide diffusion layer. Finally, the hardened titanium alloy element may be recovered 916.

The foregoing description and accompanying figures illustrate the principles, preferred embodiments and modes of operation of the invention. However, the invention should not be construed as being limited to the particular embodiments discussed above. Additional variations of the embodiments discussed above will be appreciated by those skilled in the art.

Therefore, the above-described embodiments should be regarded as illustrative rather than restrictive. Accordingly, it should be appreciated that variations to those embodiments can be made by those skilled in the art without departing from the scope of the invention as defined by the following claims.

1. A turbine element for a gas turbine engine comprising:
a hardened titanium alloy comprise a titanium beryllide layer diffused to a predetermined depth from the surface of the turbine element of from approximately 0.0005 inch to approximately 0.001 inch.

2. The turbine element of claim 1, wherein the turbine element comprises at least one of a rotor blade, a nozzle guide vane, a compressor vane, a turbine vane, and a turbine nozzle ring.

3. (canceled)

4. The turbine element of claim 1, wherein the titanium beryllide layer hardness is approximately 900 HV.

5. The turbine element of claim 1, wherein the hardened titanium alloy element comprises at least one of titanium, aluminum, vanadium, nickel, palladium, molybdenum, ruthenium, zirconium, boron, beryllium, and niobium.

6. The turbine element of claim 1, wherein the titanium beryllide layer is formed by a process comprising at least one of fused salt electrolysis, chemical vapor deposition, pack cementation, and ion beam deposition.

7. The turbine element of claim 6, wherein the fused salt electrolysis further comprises:
placing the titanium alloy element in an electrolyte containing beryllium;
connecting the titanium alloy element to an electrical circuit;
heating the electrolyte;
applying a current; and
recovering the turbine element.

8. The turbine element of claim 7, wherein the electrolyte comprises at least one of alkali metal fluorides, strontium fluorides, beryllium fluorides, and barium fluorides.

9. The gas turbine element of claim 7, wherein the electrolyte is heated to a temperature from approximately 550° C. to approximately 1100° C.

10. The gas turbine element of claim 7, wherein the current density is at most approximately 190 mA/in².

11. A hardened titanium alloy element made by a process comprising the steps of:
obtaining a titanium alloy element; and
forming a titanium beryllide layer to a predetermined depth from the surface of the titanium alloy element.

12. The hardened titanium alloy element of claim 11, wherein the predetermined depth is from approximately 0.0005 inch to approximately 0.001 inch.

13. The hardened titanium alloy element of claim 11, wherein the titanium beryllide hardness is approximately 900 HV.

14. The hardened titanium alloy element of claim 11, wherein the titanium alloy element comprises at least one of a surgical implant, drilling equipment, a gas turbine element, and an aircraft landing gear element.

15. The hardened titanium alloy element of claim 11, wherein the titanium alloy element comprises at least one of titanium, aluminum, vanadium, nickel, palladium, molybdenum, ruthenium, zirconium, boron, beryllium, and niobium.

16. The hardened titanium alloy element of claim 11, wherein the titanium beryllide layer is formed by a process comprising at least one of fused salt electrolysis, chemical vapor deposition, pack cementation, and ion beam deposition.

17. The hardened titanium alloy element of claim 16, wherein the fused salt electrolysis further comprises:
placing the titanium alloy element in an electrolyte containing beryllium;
connecting the titanium alloy element to an electrical circuit;
heating the electrolyte;
applying a current; and
recovering the hardened titanium alloy element.

18. The hardened titanium alloy element of claim 17, wherein the electrolyte comprises at least one of alkali metal fluorides, strontium fluorides, beryllium fluorides, and barium fluorides.

19. The hardened titanium alloy element of claim 17, wherein the electrolyte is heated to a temperature from approximately 550° C. to approximately 1100° C.

20. The hardened titanium alloy element of claim 17, wherein the current density is at most approximately 190 mA/in².

21. A method of increasing the hardness of a titanium alloy element comprising:
obtaining a titanium alloy element;
treating a surface of the titanium alloy with beryllium using a diffusion process; and
forming a titanium beryllide diffusion layer to a predetermined depth from the surface of the titanium alloy element.

22. The method of claim 21, wherein the predetermined depth from the surface is approximately 0.0005 inch to approximately 0.001 inch.

23. The method of claim 21, wherein the titanium beryllide layer hardness is approximately 900 HV.

24. The method of claim 21, wherein the titanium alloy element comprises at least one of a surgical implant, drilling equipment, a gas turbine element, and an aircraft landing gear element.

25. The method of claim 21, wherein the titanium alloy element comprises at least one of titanium, aluminum, vanadium, nickel, palladium, molybdenum, ruthenium, zirconium, boron, beryllium and niobium.

26. The method of claim 21, wherein the diffusion process comprises at least one of fused salt electrolysis, chemical vapor deposition, pack cementation, and ion beam deposition.

27. The method of claim 26, wherein the fused salt electrolysis comprises:
placing the titanium alloy element in an electrolyte containing beryllium;
connecting the titanium alloy element to an electrical circuit;
heating the electrolyte;
applying a current; and
recovering the element made of titanium alloy.

28. The method of claim 26, wherein the electrolyte comprising at least one of alkali metal fluorides, strontium fluorides, beryllium fluorides, and barium fluorides, is approximately 550° C. to approximately 1100° C. and the current has a maximum density of approximately 190 mA/in².

29. A turbine element for a gas turbine engine comprising:
a titanium alloy element treated by a fused salt electrolysis process wherein an electrolyte containing beryllium is heated to a temperature from about 550° C. to about 1100° C. and the current density is at most about 190 mA/in² so as to form a titanium beryllide layer to a predetermined depth from approximately 0.0005 inch to approximately 0.001 inch from the surface of the titanium alloy element.

30. The turbine element of claim 29, wherein the gas turbine element comprises at least one of a rotor blade, a nozzle guide vane, a compressor vane, a turbine vane, and a turbine nozzle ring.
